(19) United States
(12) Patent Application Publication
(10) Pub. No.: US 2023/0176474 A1
(43) Pub. Date: Jun. 8, 2023

(54) METHOD FOR INSPECTING A PHOTOMASK CONTAINED IN A TRANSPARENT POD

(71) Applicant: CHI-CHUNG CHEN, Tainan City (TW)

(72) Inventor: CHI-CHUNG CHEN, Tainan City (TW)

(21) Appl. No.: 17/858,077

(22) Filed: Jul. 6, 2022

(30) Foreign Application Priority Data
Dec. 8, 2021 (TW) 110145911

(51) Int. Cl. G03F 1/84; G03F 1/66

(52) U.S. Cl. CPC G03F 1/84; G03F 1/66

(57) ABSTRACT

A method is provided for inspecting a photomask. The photomask is formed with upper and lower faces and four lateral faces. The method includes using a transparent pod to contain the photomask, inserting the transparent pod in an inspecting machine, using a light source to cast light over one of the upper and lower faces of the photomask, using an image sensor to receive at least some of the light from the upper or lower face of the photomask via the transparent pod, and determining whether there is contamination on the upper or lower face of the photomask based on the light received by the image sensor.

### BACKGROUND OF INVENTION

### 1. Field of Invention

The present invention relates to inspection of a face of a photomask and, more particularly, to inspection of a face of a photomask contained in a transparent pod to minimize risks of contaminating the photomask during the inspection and maximize the yield of production of semiconductor products.

### 2. Related Prior Art

Photomasks are used in photolithography. During storage or transportation of a photomask, the photomask is very likely to suffer defects such as particles or smog caused by materials such as gas used in the photolithography, particles peeled from parts used in the photolithography, oil dropped from any of the parts, and/or other contaminants caused by deposition of and chemical reaction of gaseous molecules. Therefore, during the transportation or storage, the photomask is contained in a highly clean, air-tight and antistatic pod, Reticle SMIF Pod (“RSP”) to avoid contamination.

To avoid contamination of the surface of the photomask before or during the lithography, an inspecting machine is operated to inspect the surface of the photomask regularly or irregularly. Conventionally, a robot is operated to take the photomask from the pod before the inspection. The surface of the photomask can be contaminated. Abrasion or collision can happen to the photomask to produce particles or static charges that render the face of the photomask more vulnerable to contamination. In such cases, the photomask must be cleaned and/or repaired. Such cleaning or repairing inevitably reduces the life of the photomask and jeopardize the yield of production of semiconductor products. Hence, there is a need for more spare photomasks, and this inevitably increases the cost of the production of the semiconductor products.

The present invention is therefore intended to obviate or at least alleviate the problems encountered in the prior art.

### SUMMARY OF INVENTION

It is an objective of the present invention to provide a method for inspecting a photomask contained in a transparent pod so that two opposite faces of the photomask can be inspected synchronously.

It is another objective of the present invention to provide a method for inspecting a photomask contained in a transparent pod without having to use a mechanism to take the photomask from the transparent pod.

To achieve the foregoing objectives, the method includes using a transparent pod to contain the photomask, inserting the transparent pod in an inspecting machine, using a light source to cast light over a face of the photomask, using an image sensor to receive at least some of the light from the face of the photomask via the transparent pod, and determining whether there is contamination on the face of the photomask based on the light received by the image sensor.

Other objectives, advantages and features of the present invention will be apparent from the following description referring to the attached drawings.

### BRIEF DESCRIPTION OF DRAWINGS

The present invention will be described via detailed illustration of the preferred embodiment referring to the drawings wherein:

FIG. 1 is a flow chart of a method for inspecting a photomask contained in a transparent pod according to the preferred embodiment of the present invention;

FIG. 2 is a cross-sectional view of an inspecting machine and a transparent pod used in the method shown in FIG. 1;

FIG. 3 is a perspective view of the transparent pod shown in FIG. 2;

FIG. 4 is an exploded view of the transparent pod shown in FIG. 3;

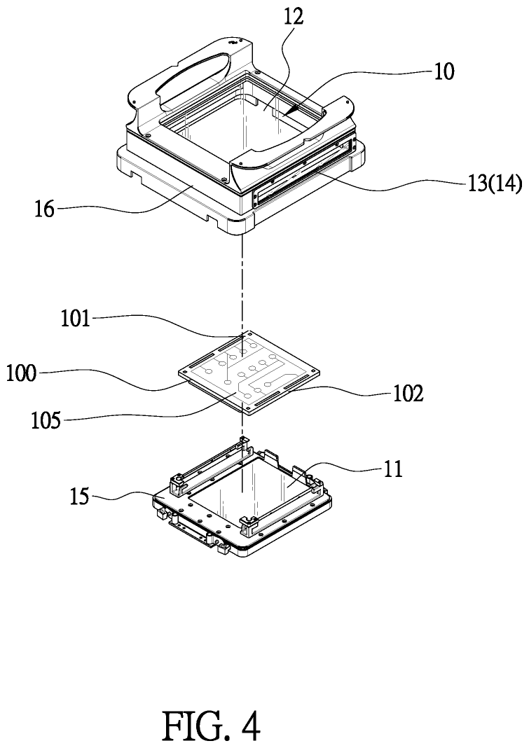

FIG. 5 is a top view of the transparent pod shown in FIG. 3; and

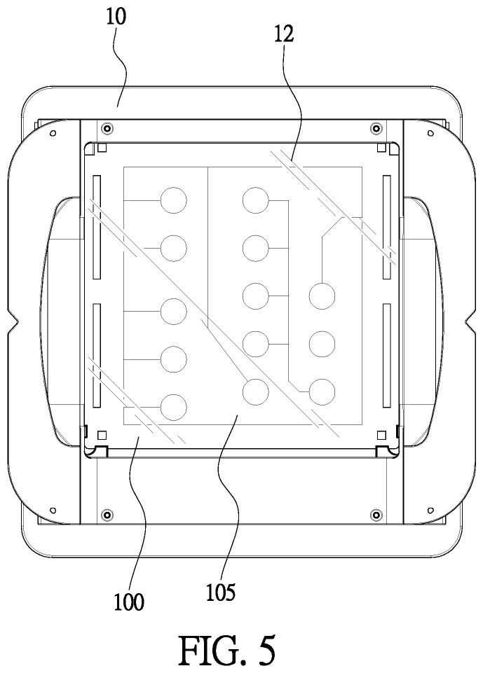

FIG. 6 is a side view of the transparent pod shown in FIG. 3.

### DETAILED DESCRIPTION OF PREFERRED EMBODIMENT

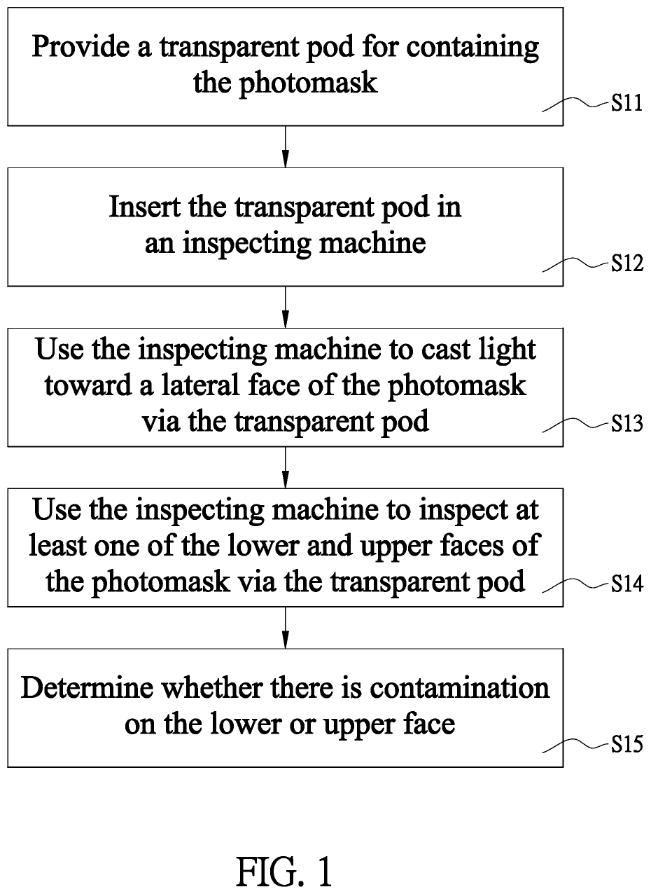

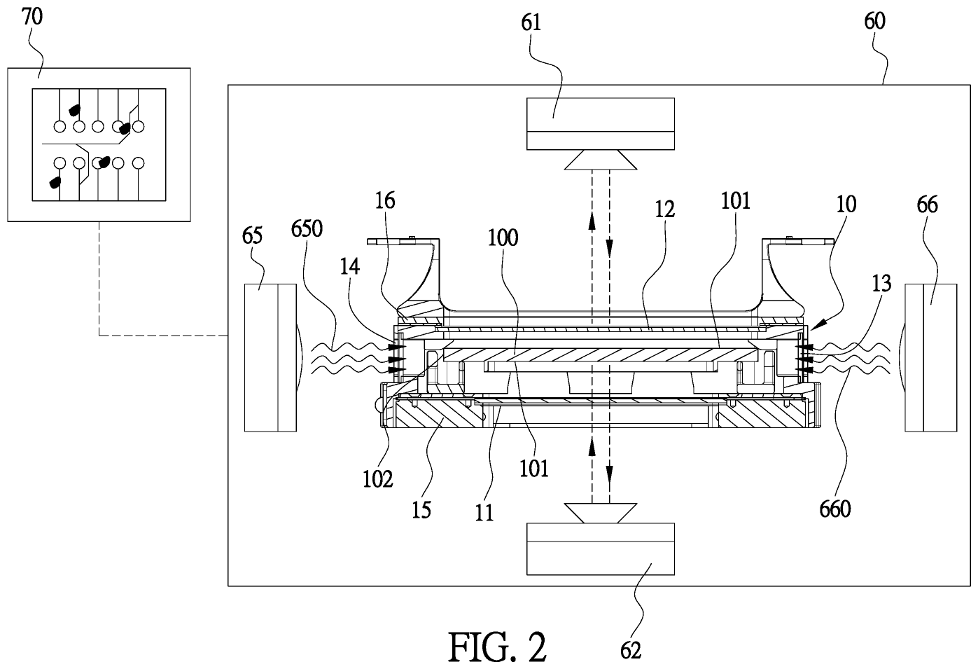

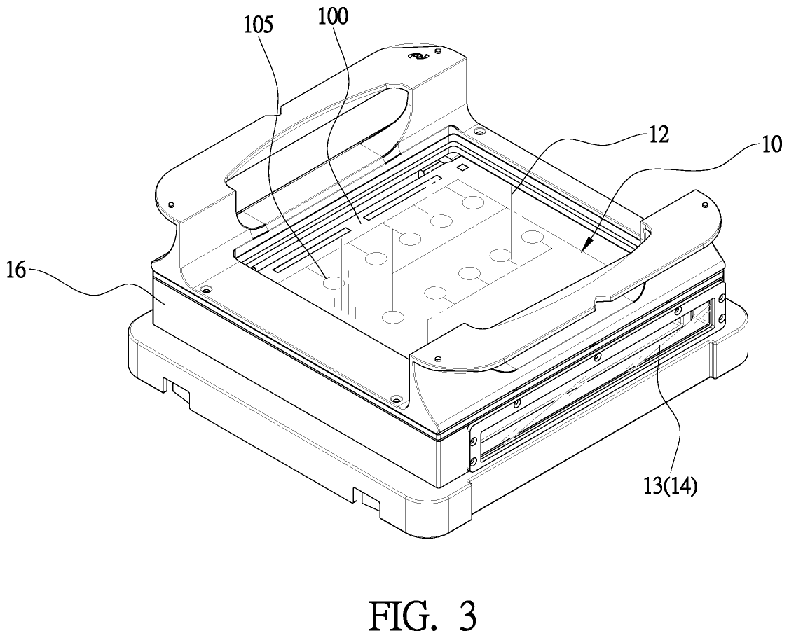

Referring to FIGS. 1 and 2, there is shown a method for inspecting a photomask 100 according to the preferred embodiment of the present invention. The photomask 100 includes lower and upper faces 101 and four lateral faces 102. The lower and upper faces 101 are in parallel to each other. The lower and upper faces 101 are rectangular faces. Accordingly, the lateral faces 102 are classified into two pairs of two lateral faces 102 in parallel to each other. The lower or upper face 101 is formed with a pattern 105 (FIG. 3) corresponding to a layout of a circuit.

The method includes providing a transparent pod for containing the photomask 100 at S11, inserting the transparent pod in an inspecting machine 60 at S12, providing a light source to cast light toward a lateral face of the photomask 100 at S13, providing an image sensor to inspect at least one of the lower and upper faces 101 of the photomask 100 at S14, and determining whether there is contamination on the lower or upper face 101 at S15.

At S11, the transparent pod is provided for containing the photomask 100. The transparent pod includes a lower lens 11 corresponding to the lower face 101 and an upper lens 12 corresponding to the upper face 101. The lower and upper lenses 11 and 12 are made of a transmittance equal to or larger than 90%. Each of the lower and upper lenses 11 and 12 includes a transparent portion equal to or larger than the pattern 105 of the photomask 100.

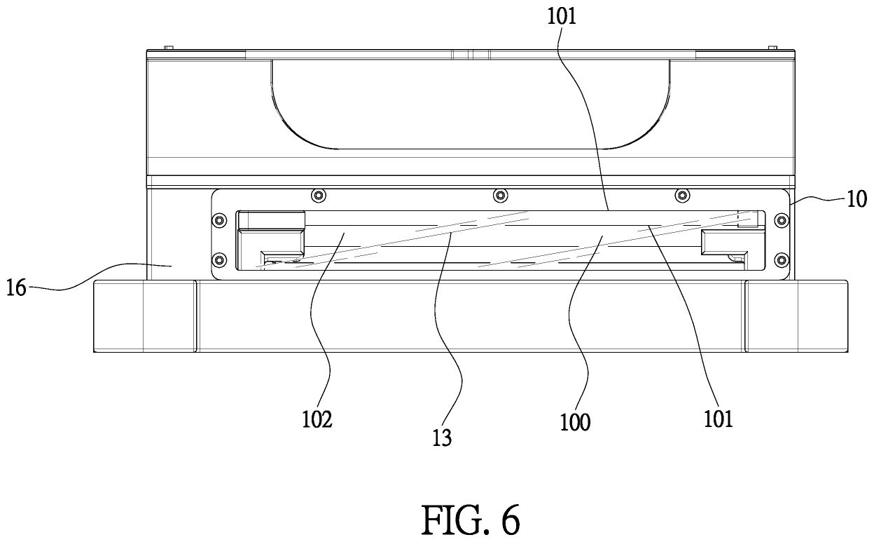

Preferably, the transparent pod includes two lateral lenses 13 and 14 corresponding to the lateral faces 102 of the photomask 100 (FIG. 2). The lateral lenses 13 and 14 are in parallel to each other. Each of the lenses 13 and 14 is made of a transmittance equal to or larger than 90%. Each of the lateral lenses 13 and 14 includes a transparent portion larger than each of the lateral faces 102 of the photomask 100 (FIG. 6).

Preferably, the lower and upper lenses 11 and 12 and the lateral lenses 13 and 14 are made of 99.995% pure quartz so that they exhibit excellent transmittance regard ultraviolet light, visible light and infrared light.

Preferably, the transparent pod includes a base 15 and a cover 16. The lower lens 11 is connected to the base 15. The upper lens 12 is connected to the cover 16. The lateral lenses 13 and 14 are connected two opposite portions of a periphery of the cover 16. The base 15 and the cover 16 can be made of metal or plastic except for the lower, upper and lateral lenses 11, 12, 13 and 14.

At S12, the transparent pod is inserted in the inspecting machine 60. The transparent pod is inserted in the inspecting machine 60 after the photomask 100 is inserted in the transparent pod. The inspecting machine 60 includes an upper image sensor 61 and lower image sensor 62. Each of the upper and lower image sensors 61 and 62 can be a CCD or CMOS sensor. The inspecting machine 60 further includes two light sources 65 and 66 corresponding to the lateral lenses 13 and 14 of the transparent pod. The light source 65 is operable to emit a ray 650. The light source 66 is operable to emit a ray 660.

Alternatively, the light sources 65 and 66 can be located corresponding to the lower and upper lenses 11 and 12 instead of the lateral lenses 13 and 14.

At S13, at least one of the light sources 65 and 66 is operated to cast light toward at least one of the lateral faces 102 of the photomask 100. At least one of the light sources 65 and 66 is operated to cast a ray 650 or 660 toward at least one of the lateral faces 102 of the photomask 100 via the lateral lens 14 or 13 after the transparent pod is inserted in the inspecting machine 60. The ray 650 or 660 travels over the lower or upper face 101 of the photomask 10.

Alternatively, at least one of the light sources 65 and 66 is operated to cast a ray 650 or 660 onto the lower or upper face 101 of the photomask 100 via at least one of the lower and upper lenses 11 and 12. In such a case, it is preferred that an image sensor be located on a side of the photomask 100 opposite to the light source 65 or 66.

At S14, at least one of the image sensors 61 and 62 is operated to inspect the upper or lower face 101 of the photomask 100. As mentioned above, the ray 650 or 660 travels over the lower or upper face 101 of the photomask 10. If there is contamination on the upper or lower face 101, the ray 650 or 660 will be scattered by the contamination. The image sensor 61 or 62 will sense the scattered light.

At S15, it is determined whether there is contamination on the upper or lower face 101. A human/machine interface unit 70 is electrically connected to the inspecting machine 60. The human/machine interface unit 70 can be a touch panel. The human/machine interface unit 70 is operated to show an image detected by the image sensor 61 or 62. A worker is allowed to observe the image and determine whether there is contamination on the upper or lower face 101.

As discussed above, in the method for inspecting a photomask according to the present invention, the photomask 100 is inserted in the transparent pod. The ray 650 or 660 is cast to the photomask 100 from the light source 65 or 66 via the lateral lens 13 or 14. Then, light travels to the image sensors 61 or 62 from the upper or lower face 101 of the photomask 100 via the lower lens 11 or the upper lens 12.

As discussed above, the photomask 100 is contained in and hence protected by the transparent pod throughout the inspection. Hence, the risk of contamination of the photomask 100 is minimized. Moreover, the yield of production of semiconductor produces by use of the photomask 100 is maximized. Furthermore, the size and cost of the inspecting machine 60 are minimized because there is no need to include a mechanism for taking the photomask 100 from the transparent pod to allow inspection of the photomask 100.

The present invention has been described via the illustration of the preferred embodiment. Those skilled in the art can derive variations from the preferred embodiment without departing from the scope of the present invention. Therefore, the preferred embodiment shall not limit the scope of the present invention defined in the claims.

1. A method for inspecting a photomask formed with upper and lower faces and four lateral faces, the method comprising the steps of:
using a transparent pod to contain the photomask;
providing an inspecting machine with a light source and an image sensor;
inserting the transparent pod in the inspecting machine;
using the light source to cast light over one of the upper and lower faces of the photomask via the transparent pod;
using the image sensor to receive at least some of the light from the upper or lower face of the photomask via the transparent pod; and
determining whether there is contamination on the upper or lower face of the photomask based on the light received by the image sensor.

2. The method according to claim 1, wherein the step of using a light source to cast light over one of the upper and lower faces of the photomask comprises the step of using the light source to cast a ray onto the upper or lower face via an upper or lower portion of the transparent pod.

3. The method according to claim 1, wherein the step of using a light source to cast light over one of the upper and lower faces of the photomask comprises the step of using the light source to cast a ray toward one of the lateral faces of the photomask via a lateral portion of the transparent pod so that the ray travels over the upper or lower face of the photomask.

4. A transparent pod for containing a photomask formed with upper and lower faces and four lateral faces, the transparent pod comprising a lower lens corresponding to the lower face of the photomask and an upper lens corresponding to an upper face of the photomask, wherein the lower and upper lenses are made of transmittance equal to or larger than 90%.

5. The transparent pod according to claim 4, comprising two lateral lenses corresponding two opposite ones of the lateral faces of the photomask, wherein the lateral lenses are made of transmittance equal to or larger than 90%.

6. The transparent pod according to claim 5, comprising a base and a cover for covering the base, wherein the lower lens is connected to the base, wherein the upper lens is connected to the cover, and wherein the lateral lenses are connected to opposite portions of a periphery of the cover.

7. The transparent pod according to claim 6, wherein the base and the cover are made of plastic except for the lower, upper and lateral lenses.

8. The transparent pod according to claim 6, wherein the base and the cover are made of metal except for the lower, upper and lateral lenses.

9. The transparent pod according to claim 4, wherein the lower and upper lenses are made of 99.995% pure quartz.

10. The transparent pod according to claim 5, wherein the lateral lenses are made of 99.995% pure quartz.
